(19) United States
(12) Patent Application Publication
(10) Pub. No.: US 2019/0348552 A1
(43) Pub. Date: Nov. 14, 2019

(54) Modular Photovoltaic Panel

(71) Applicant: Vernon Stoudt, Salinas, CA (US)

(72) Inventor: Vernon Stoudt, Salinas, CA (US)

(21) Appl. No.: 16/114,963

(22) Filed: Aug. 28, 2018

Related U.S. Application Data
(60) Provisional application No. 62/668,494, filed on May 8, 2018.

(51) Int. Cl. H01L 31/042; H02S 40/22; H01L 31/054; H01L 31/02

(52) U.S. Cl. CPC H01L 31/042; H01L 31/02008; H01L 31/0547; H02S 40/22

(57) ABSTRACT

A modular photovoltaic panel designed to improve the amount of energy produced by a photovoltaic panel. The modular photovoltaic panel includes photovoltaic modules that align to create a panel. Each photovoltaic module has a base, with a perimeter and four sidewalls extending from the perimeter of the base. A mirror is on each base of each photovoltaic module. In one embodiment, the mirror concave. In another embodiment, the mirror is convex. Several solar cells are disposed on each sidewall of each photovoltaic module, such that the mirror is designed to reflect the light to all four walls, thereby increasing the total amount of energy produced. In this way, a user is able to increase the total amount of energy produced from a photovoltaic panel while utilizing a smaller overall area.

### CROSS REFERENCE TO RELATED APPLICATIONS

This application claims the benefit of U.S. Provisional Application No. 62/668,494 filed on May 8, 2018. The above identified patent application is herein incorporated by reference in its entirety to provide continuity of disclosure.

### BACKGROUND OF THE INVENTION

The present invention relates to photovoltaic panels. More specifically, the invention provides a modular photovoltaic panel comprised of a plurality of photovoltaic modules, each module having a mirrored base and four sidewalk composed of a plurality of solar cells.

Solar power continues to improve in both cost and consumer usability. However, the photovoltaic panels used to produce solar power are not as efficient as other forms of renewable energy. Photons produced by the sun hit the photovoltaic panel and excite the electrons inside the photovoltaic panel, converting the electrons to electricity. Unfortunately, the total amount of energy produced is limited by the area of the photovoltaic panels, and it can be difficult to find enough space to produce the total energy required. Thus, an improved modular photovoltaic panel that can increase the total amount of energy produced is desired.

### SUMMARY OF THE INVENTION

In view of the foregoing disadvantages inherent in the known types of photovoltaic panels now present in the known art, the present invention provides a modular photovoltaic panel wherein the same can be utilized for providing convenience for the user when desiring to efficiently increase the amount of electricity generated.

The present system comprises a modular photovoltaic panel wherein a plurality of photovoltaic modules are aligned to create a panel. Each photovoltaic module comprises a base, wherein the base has a perimeter with four sidewalk extending therefrom. A mirror is disposed on each base of each photovoltaic module. In one embodiment, the mirror is concave. In another embodiment, the mirror is convex. A plurality of solar cells are disposed on each side all of each photovoltaic module. The mirrored base is configured to reflect the sunlight onto the four walls, thereby producing three times as much energy as a traditional photovoltaic panel. In this way, a user is able to increase the total amount of energy produced from a photovoltaic panel while utilizing a smaller overall area.

### BRIEF DESCRIPTION OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows an exploded perspective view of an embodiment of a photovoltaic module.

FIG. 2 shows a cross-sectional view of an embodiment of a photovoltaic module.

FIG. 3 shows a perspective view of an embodiment of the modular photovoltaic panel.

### DETAILED DESCRIPTION OF THE INVENTION

Reference is made herein to the attached drawings. Like reference numerals are used throughout the drawings to depict like or similar elements of the modular photovoltaic panel. The figures are intended for representative purposes only and should not be considered to be limiting in any respect.

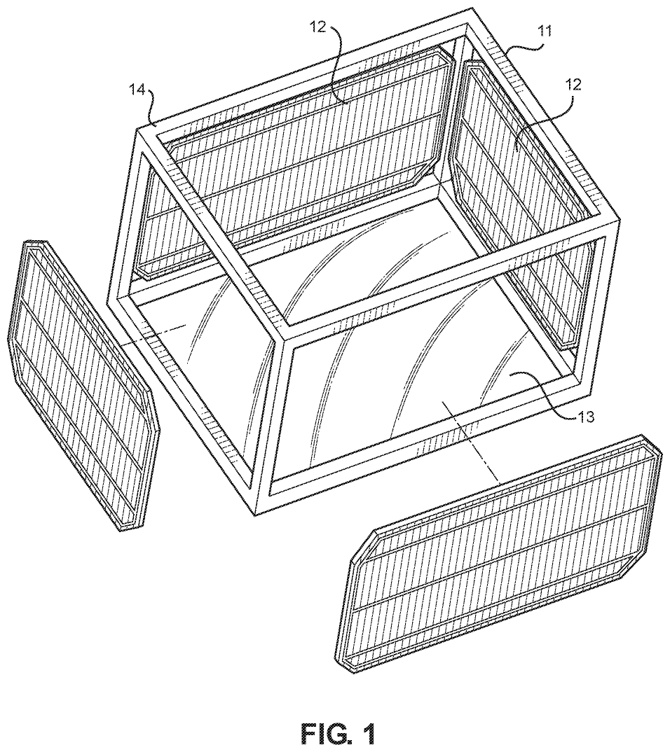

Referring now to FIG. 1, there is shown an exploded perspective view of an embodiment of a photovoltaic module. A modular photovoltaic panel comprises a plurality of photovoltaic modules 11. Each of the photovoltaic modules 11 have a base 13 and at least one sidewall 12 extending from a perimeter of the base 13. In the illustrated embodiment, the base 13 comprises four side walls 12 extending from the perimeter of the base 13. A mirror is disposed on the base 13 and a plurality of solar cells are disposed on each sidewall 12, such that the mirror 13 reflects sunlight towards the solar cells, thereby allowing one photovoltaic module to produce a greater amount of energy than is traditionally generated. The solar cells are composed of amorphous silicon or cadmium telluride, or any other suitable material configured to absorb solar energy.

In the illustrated embodiment, each sidewall of solar cells 12 extends upwardly from the mirror base 13, such that each sidewall of solar cells 12 is perpendicular to the mirror base 13. Thus, in the illustrated embodiment, the photovoltaic module 11 forms a cube between the four sidewalls, having an open upper end allowing sunlight to enter therein, thereby allowing the mirror 13 to reflect light onto each sidewall of solar cells 12. In other embodiments, the sidewalls of solar cells 12 are configured to be oriented at an acute angle with respect to the mirror base 13, such that the sidewalls of solar cells 12 capture a greater total number of refracted rays from the mirror 13.

In one embodiment, the photovoltaic module 11 further comprises a frame 14, configured to provide a mount for the base 13 and each sidewall 12. The frame 14 additionally provides a plurality of modules 11 to fit flush against one another in a grid like arrangement. In the illustrated embodiment, the mirror base 13 and each sidewall of solar cells 12 are removably secured to the frame 14. In this way, should the mirror base 13 or sidewall of solar cells 12 become damaged, the base 13 or sidewall 12 can be repaired or replaced without exchanging the entire photovoltaic module 11.

The mirror base 13 is configured to reflect light towards each sidewall of solar cells 12. In the illustrated embodiment, the mirror base 13 is convex, such that it is curved like the exterior of a sphere and extends outward towards each sidewall of solar cells 12. The convex mirror base 13 thereby allows the sunlight to reflect therearound in a more efficient manner when the sun is overhead, such that a greater proportion of energy is channeled to each sidewall of solar cells 12.

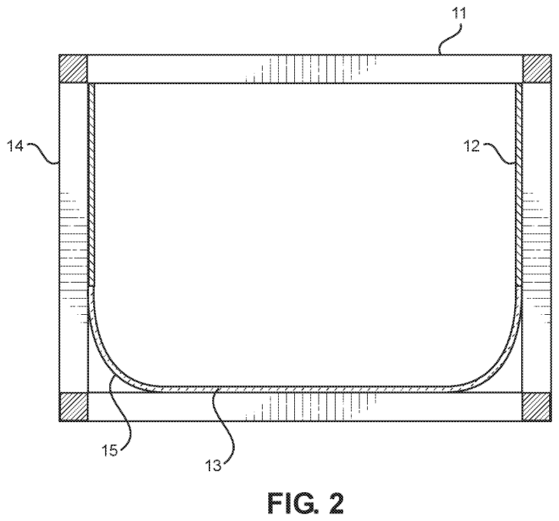

Referring now to FIG. 2, there is shown a side view of an embodiment of a photovoltaic module. In the illustrated embodiment, each photovoltaic module 11 features a concave mirror base 13, such that each corner 15 of the mirror base 13 is curved upward towards the sidewall of solar cells 12, and the mirror base 13 forms a bowl. In this way, the mirror base 13 reflects a greater proportion of light towards each sidewall of solar cells 12 when the sun is rising in the sky or setting in the sky, i.e. not directly overhead the photovoltaic module. In this embodiment, the mirror base 13 is still removably secured to the frame 14, such that the user can exchange the mirror base 13 should it become damaged.

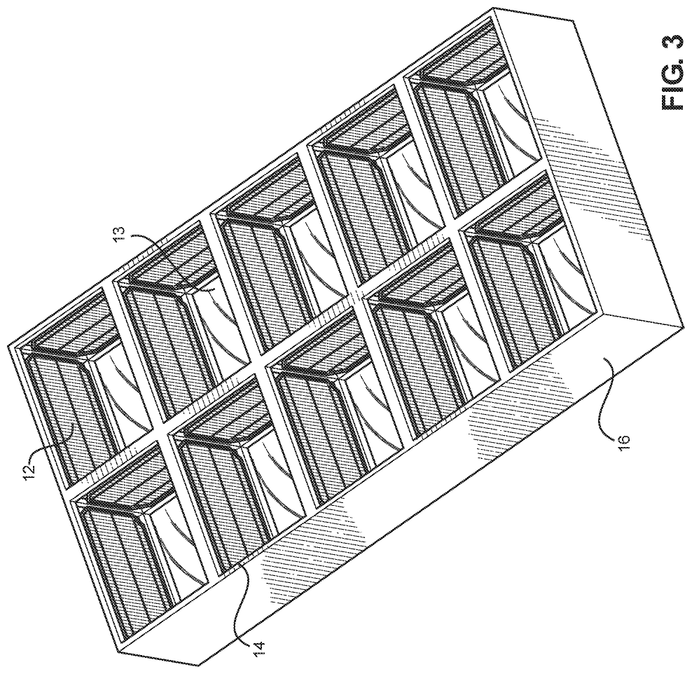

Referring to FIG. 3, there is shown a perspective view of an embodiment of the modular photovoltaic panel. In the illustrated embodiment, the photovoltaic modules are configured to fit flush within a larger frame 16, thereby forming the photovoltaic panel. In other embodiments, however, the photovoltaic modules are configured to affix to one another to form the modular photovoltaic panel 16, through magnetic fasteners or other suitably secure means. The modular photovoltaic panel 16 is configured to be modular, such that the modular photovoltaic panel 16 can comprise a plurality of photovoltaic modules. In the modular photovoltaic panel 16, the frame 14 of each photovoltaic module is disposed flush against one another, such that the photovoltaic modules are arranged in a grid-like display. The mirror bases 13 are each disposed to face the sun, such that each mirror base 13 can reflect the sunlight onto the plurality of sidewall of solar cells 12 therearound. Further, each modular photovoltaic panel 16 is operably connected to at least one power storage unit, such as a battery, wherein the power storage unit is configured to store the energy output produced by the plurality of solar cells 12 disposed in each photovoltaic module.

In operation, a user will choose a plurality of photovoltaic modules, each photovoltaic module having a mirror base with four sidewalk of solar cells extending therefrom to create a cubic structure, wherein the mirror base is concave or convex, depending on the embodiment utilized. The user will then affix each photovoltaic module to one another such that a modular photovoltaic panel of a desired size and shape is created. The modular photovoltaic panel is operably connected to a battery, thereby allowing a user to effectively convert solar energy to usable electrical energy. In this way, a user can create a modular solar panel that is three times more efficient than a traditional solar panel.

It is therefore submitted that the instant invention has been shown and described in various embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1) A modular photovoltaic panel, comprising:
a plurality of photovoltaic modules aligned to create a panel;
wherein each photovoltaic module comprises a base, having a perimeter and at least one sidewall extending therefrom;
a mirror disposed on each base of each photovoltaic module;
a plurality of solar cells disposed on each sidewall of each photovoltaic module.

2) The modular photovoltaic panel of claim 1, wherein the mirror comprises the entirety of the base.

3) The modular photovoltaic panel of claim 1, wherein the mirror is concave.

4) The modular photovoltaic panel of claim 1, wherein the mirror is convex.

5) The modular photovoltaic panel of claim 1, wherein each photovoltaic module is enclosed by a frame.

6) The modular photovoltaic panel of claim 5, wherein each sidewall and base of each photovoltaic module is removably securable from the frame.

7) The modular photovoltaic panel of claim 1, wherein the solar cells are composed from a material selected from the group consisting of amorphous silicon, cadmium telluride, and copper indium gallium selenide.

8) The modular photovoltaic panel of claim 1, wherein each photovoltaic module comprises a fastener on an external surface thereon such that the photovoltaic modules are configured to affix to one another to form the modular photovoltaic panel.

9) The modular photovoltaic panel of claim 8, wherein the fastener is a magnetic fastener.

10) The modular photovoltaic panel of claim 1, wherein four sidewalk are defined, each sidewall of the four sidewalk having a plurality of solar panels thereon.
